(19) United States
(12) Patent Application Publication
(10) Pub. No.: US 2014/0183554 A1
(43) Pub. Date: Jul. 3, 2014

(54) SCHOTTKY BARRIER DIODE AND METHOD OF MANUFACTURING THE SAME

(71) Applicant: Hyundai Motor Company, Seoul (KR)

(72) Inventors: Kyoung-Kook HONG, Hwaseong-Si (KR); Jong Seok LEE, Suwon-si (KR); Dae Hwan CHUN, Gwangmyung-si (KR); Youngkyun JUNG, Seoul (KR)

(73) Assignee: HYUNDAI MOTOR COMPANY, Seoul (KR)

(21) Appl. No.: 14/066,460

(22) Filed: Oct. 29, 2013

(30) Foreign Application Priority Data
Dec. 28, 2012 (KR) 10-2012-0157484

(51) Int. Cl. H01L 29/06; H01L 21/04; H01L 29/66; H01L 29/872; H01L 29/16

(52) U.S. Cl. CPC H01L 29/0619; H01L 29/872; H01L 29/1608; H01L 29/6606; H01L 21/0475
USPC 257/77; 438/494

(57) ABSTRACT

A Schottky barrier diode includes: an n+ type silicon carbide substrate; an n− type epitaxial layer disposed on a first surface of the n+ type silicon carbide substrate and includes an electrode area and a terminal area positioned outside of the electrode area; a first trench and a second trench disposed on the n− type epitaxial layer in the terminal area; a p area disposed under the first trench and the second trench; a Schottky electrode disposed on the n− type epitaxial layer in the electrode area; and an ohmic electrode disposed on a second surface of the n+ type silicon carbide substrate, wherein the first trench and the second trench are adjacently positioned to form a step.

### CROSS-REFERENCE TO RELATED APPLICATION

This application claims priority to and the benefit of Korean Patent Application No. 10-2012-0157484 filed in the Korean Intellectual Property Office on Dec. 28, 2012, the entire contents of which are incorporated herein by reference.

### BACKGROUND OF THE DISCLOSURE

(a) Field of the Disclosure

The present disclosure relates to a Schottky barrier diode including silicon carbide (SiC) and a method of manufacturing the same.

(b) Description of the Related Art

A Schottky barrier diode (SBD) does not use a PN junction, unlike a general PN diode, but instead uses a Schottky junction in which an electrode and a semiconductor are bonded An SBD may have relatively fast switching characteristics, and may have turn-on voltage characteristics lower than that of a PN diode.

In such an SBD, as an electric field is concentrated in an edge portion of an electrode, there is a problem that a breakdown voltage can not be secured by a theoretical breakdown value of the SBD.

The above information disclosed in this Background section is only for enhancement of understanding of the background of the disclosure and therefore it may contain information that is not prior art.

### SUMMARY OF THE DISCLOSURE

The present disclosure has been made in an effort to provide a Schottky barrier diode and a method of manufacturing the same having the advantages of improving a breakdown voltage of the Schottky barrier diode by distributing an electric field concentration in an edge portion of an electrode in the Schottky barrier diode.

An exemplary embodiment of the present disclosure provides a Schottky barrier diode including: an n+ type silicon carbide substrate; an n− type epitaxial layer disposed on a first surface of the n+ type silicon carbide substrate and including an electrode area and a terminal area positioned outside of the electrode area; a first trench and a second trench disposed on the n− type epitaxial layer in the terminal area; a p area disposed under the first trench and the second trench; a Schottky electrode disposed on the n− type epitaxial layer in the electrode area; and an ohmic electrode disposed on a second surface of the n+ type silicon carbide substrate, wherein the first trench and the second trench are adjacently positioned to form a step.

A bottom of the first trench may be disposed lower than a bottom of the second trench.

The first trench may be disposed adjacent to the electrode area.

The p area may extend to an upper surface of the n− type epitaxial layer in the terminal area adjacent to the second trench.

The Schottky electrode may extend to the terminal area to make contact with the p area.

Another exemplary embodiment of the present disclosure provides a method of manufacturing a Schottky barrier diode, the method including: forming an n− type epitaxial layer, including an electrode area and a terminal area positioned outside of the electrode area, with a first epitaxial growth on a first surface of an n+ type silicon carbide substrate; forming a preliminary trench by etching a portion of the n− type epitaxial layer in the terminal area; forming a first trench and a second trench by etching a portion of the preliminary trench; forming a p area under the first trench, the second trench, and an upper surface of the n− type epitaxial layer in the terminal area adjacent to the second trench, by injecting p-ions into the first trench, the second trench, and the upper surface of the n− type epitaxial layer in the terminal area adjacent to the second trench; forming a Schottky electrode on the n− type epitaxial layer in the electrode area; and forming an ohmic electrode on a second surface of the n+ type silicon carbide substrate, wherein the first trench and the second trench are adjacently positioned to form a step.

Yet another exemplary embodiment of the present disclosure provides a method of manufacturing a Schottky barrier diode, the method including: forming a first preliminary n− type epitaxial layer, including an electrode area and a terminal area positioned outside of the electrode area, with a second epitaxial growth on a first surface of an n+ type silicon carbide substrate; forming a first mask on a portion of the first preliminary n− type epitaxial layer in the terminal area; forming a second preliminary n− type epitaxial layer with a third epitaxial growth on the first preliminary n− type epitaxial layer; forming a second mask on the first mask and on a portion of the second preliminary n− type epitaxial layer in the terminal area; forming a third preliminary n− type epitaxial layer with a fourth epitaxial growth on the second preliminary n− type epitaxial layer, thereby forming an n− type epitaxial layer; forming a first trench and a second trench by removing the first mask and the second mask; forming a p area under the first trench, the second trench, and an upper surface of the n− type epitaxial layer in the terminal area adjacent to the second trench, by injecting p-ions into the first trench, the second trench, and the upper surface of the n− type epitaxial layer in the terminal area adjacent to the second trench; forming a Schottky electrode on the n− type epitaxial layer in the electrode area; and forming an ohmic electrode on a second surface of the n+ type silicon carbide substrate, wherein the first trench and the second trench are adjacently positioned to form a step.

The second mask may have a width larger than a width of the first mask.

The first mask and the second preliminary n− type epitaxial layer may have the same thickness.

The second mask and the third preliminary n− type epitaxial layer may have the same thickness.

Yet another exemplary embodiment of the present disclosure provides a method of manufacturing a Schottky barrier diode, the method including: forming an n− type epitaxial layer, including an electrode area and a terminal area positioned outside of the electrode area, with an epitaxial growth on a first surface of an n+ type silicon carbide substrate, and forming a first buffer layer on the n− type epitaxial layer; forming a first buffer layer pattern that exposes the n− type epitaxial layer in the terminal area by etching a portion of the first buffer layer positioned in the terminal area; forming a second buffer layer on the first buffer layer pattern and on the n− type epitaxial layer in the terminal area; forming a second buffer layer pattern that exposes the first buffer layer pattern by etching a portion of the second buffer layer positioned on the first buffer layer pattern; forming a third buffer layer pattern that exposes a first portion of the n− type epitaxial layer by performing a first isotropic etching of the second buffer layer pattern in a horizontal direction; forming a preliminary trench by etching the first portion of the n− type epitaxial layer; forming a fourth buffer layer pattern that exposes a second portion of the n− type epitaxial layer by performing a second isotropic etching of the third buffer layer pattern in a horizontal direction; forming a first trench and a second trench by etching the preliminary trench and the second portion of the n− type epitaxial layer, respectively; forming a fifth buffer layer pattern that exposes a third portion of the n− type epitaxial layer by performing a third isotropic etching of the fourth buffer layer pattern in a horizontal direction; forming a p area under the first trench, the second trench, and the third portion of the n− type epitaxial layer by injecting p-ions into the first trench, the second trench, and the third portion of the n− type epitaxial layer; forming a Schottky electrode on the n− type epitaxial layer in the electrode area; and forming an ohmic electrode on a second surface of the n+ type silicon carbide substrate, wherein the first trench and the second trench are adjacently positioned to form a step.

The first buffer layer pattern may be positioned in the electrode area, and the second buffer layer pattern may be positioned in the terminal area, and the first buffer layer pattern and the second buffer layer pattern may contact each other.

The first isotropic etching may be performed in a contact portion of the first buffer layer pattern and the second buffer layer pattern.

The preliminary trench and the third buffer layer pattern may be adjacently positioned, and the second isotropic etching may be performed in a portion of the third buffer layer pattern adjacent to the preliminary trench.

The second trench and the fourth buffer layer pattern may be adjacently positioned, and the third isotropic etching may be performed in a portion of the fourth buffer layer pattern adjacent to the second trench.

The first buffer layer may be made of amorphous carbon, and the second buffer layer may be formed with an oxide layer.

According to an exemplary embodiment of the present disclosure, by adjacently positioning a first trench and a second trench that form a step in a terminal area and by disposing a p area under the first trench, the second trench, and an upper surface of an n− type epitaxial layer in a terminal area, an electric field to be concentrated in an edge portion of a Schottky electrode can be distributed.

Accordingly, a breakdown voltage of an SBD can be improved.

### BRIEF DESCRIPTION OF THE DRAWINGS

FIG. 1 is a cross-sectional view illustrating a Schottky barrier diode according to an exemplary embodiment of the present disclosure.

FIGS. 2 to 6 are cross-sectional views sequentially illustrating a method of manufacturing a Schottky barrier diode according to an exemplary embodiment of the present disclosure.

FIGS. 7 to 13 are cross-sectional views sequentially illustrating a method of manufacturing a Schottky barrier diode according to another exemplary embodiment of the present disclosure.

FIGS. 14 to 24 are cross-sectional views sequentially illustrating a method of manufacturing a Schottky barrier diode according to another exemplary embodiment of the present disclosure.

FIG. 25 is a graph comparing breakdown voltages of a Schottky barrier diode according to an exemplary embodiment of the present disclosure and a conventional Schottky barrier diode.

### DETAILED DESCRIPTION OF EXEMPLARY EMBODIMENTS

Exemplary embodiments of the present disclosure will be described in detail with reference to the accompanying drawings. As those having ordinary skill in the art would realize, the described embodiments may be modified in various different ways, all without departing from the spirit or scope of the present disclosure. Exemplary embodiments introduced here are intended to provide disclosed contents and to fully transfer the spirit and scope of the present disclosure to a person having ordinary skill in the art.

In the drawings, the thickness of layers and regions are exaggerated for clarity. When it is said that a layer is positioned/disposed on another layer or substrate, it means the layer may be formed directly on the another layer or substrate or a third layer may be interposed therebetween. Like reference numerals designate like elements throughout the specification.

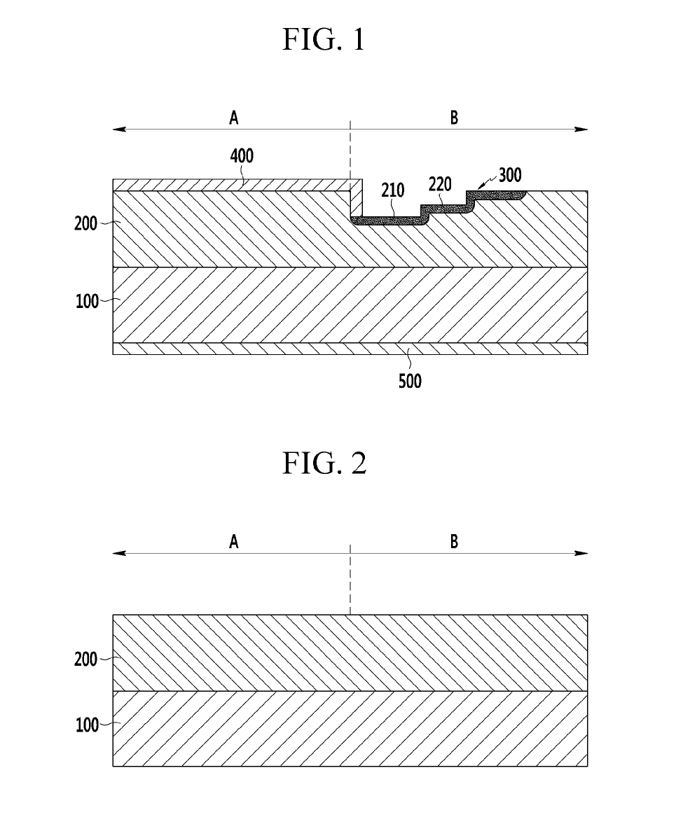

FIG. 1 is a cross-sectional view illustrating a Schottky barrier diode (SBD) according to an exemplary embodiment of the present disclosure.

Referring to FIG. 1, in the SBD according to the present exemplary embodiment, an n− type epitaxial layer 200 is disposed on a first surface of an n+ type silicon carbide substrate 100, and a Schottky electrode 400 is disposed on the n− type epitaxial layer 200. On a second surface of the n+ type silicon carbide substrate 100, an ohmic electrode 500 is disposed.

Further, the n− type epitaxial layer 200 includes an electrode area A and a terminal area B that is positioned outside of the electrode area A. The Schottky electrode 400 is disposed on the n− type epitaxial layer 200 in the electrode area A.

At the n− type epitaxial layer 200 in the terminal area B, a first trench 210 and a second trench 220 are disposed. The first trench 210 and the second trench 220 are adjacently positioned to form a step, and a bottom of the first trench 210 is disposed lower than a bottom of the second trench 220.

Further, the first trench 210 is disposed adjacent to the electrode area A, and the second trench 220 is disposed adjacent to an upper surface of the n− type epitaxial layer 200 in the terminal area B.

A p area 300 is disposed under the first trench 210 and the second trench 220. Further, the p area 300 may extend to the upper surface of the n− type epitaxial layer 200 in the terminal area B.

Further, the Schottky electrode 400 may extend to the terminal area B to make contact with the p area 300 that is disposed under the first trench 210.

In this way, by adjacently positioning the first trench 210 and the second trench 220 to form a step in the terminal area B and by disposing the p area 300 under the first trench 210, the second trench 220, and an upper surface of the n− type epitaxial layer 200 in the terminal area B, an electric field to be concentrated in an edge portion of the Schottky electrode 400 can be distributed. Accordingly, a breakdown voltage of an SBD can be improved.

Further, as a breakdown voltage is improved, a thickness of the n− type epitaxial layer 200 can be reduced and thus an on-resistance of the SBD can be reduced.

A method of manufacturing a Schottky barrier diode (SBD) according to an exemplary embodiment of the present disclosure will now be described in detail with reference to FIGS. 1 and 2 to 6.

FIGS. 2 to 6 are cross-sectional views sequentially illustrating a method of manufacturing an SBD according to an exemplary embodiment of the present disclosure.

As shown in FIG. 2, the n+ type silicon carbide substrate 100 is prepared, and the n− type epitaxial layer 200 is formed with a first epitaxial growth on a first surface of the n+ type silicon carbide substrate 100. The n− type epitaxial layer 200 includes the electrode area A and the terminal area B positioned outside of the electrode area A.

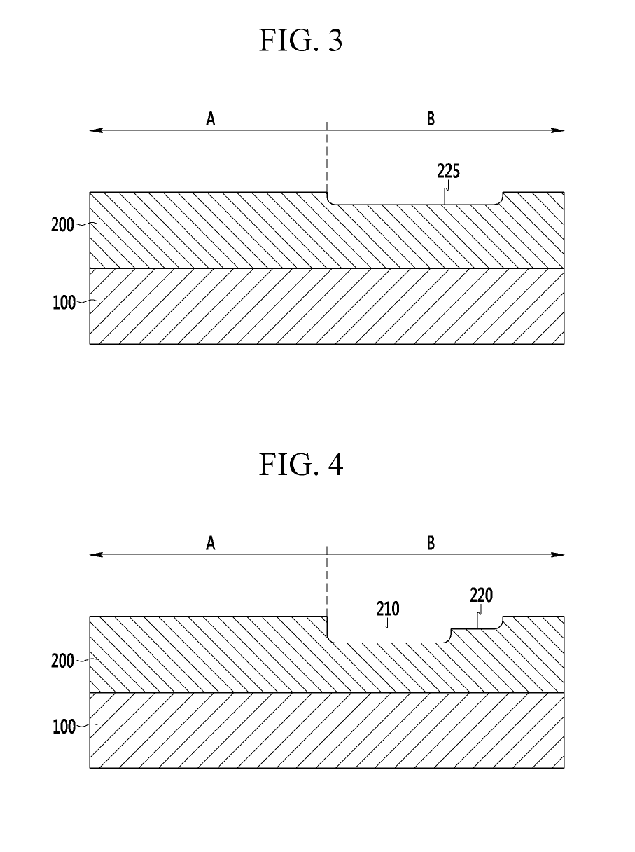

As shown in FIG. 3, by etching a portion of the n− type epitaxial layer 200 positioned in terminal area B, a preliminary trench 225 is formed.

As shown in FIG. 4, by etching a portion of the preliminary trench 225, the first trench 210 and the second trench 220 are formed. The first trench 210 and the second trench 220 are adjacently positioned to form a step, and a bottom of the first trench 210 is formed lower than a bottom of the second trench 220.

Further, the first trench 210 is positioned adjacent to the electrode area A, and the second trench 220 is positioned adjacent to an upper surface of the n− type epitaxial layer 200 in the terminal area B.

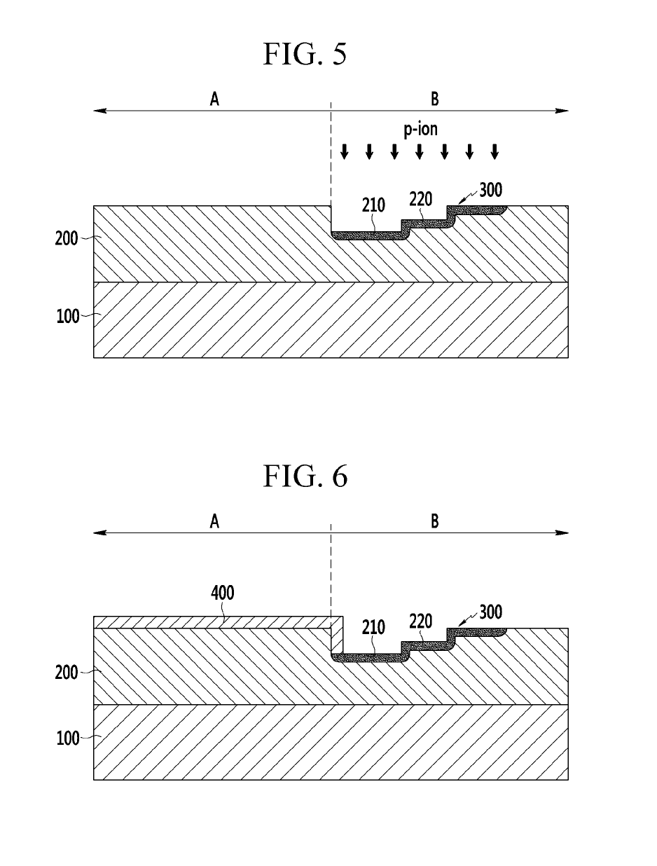

As shown in FIG. 5, by injecting p-ions into the first trench 210, the second trench 220, and a partial surface of the n− type epitaxial layer 200 in the terminal area B, the p area 300 is formed under the first trench 210, the second trench 220, and the partial surface of the n− type epitaxial layer 200 in the terminal area B.

As shown in FIG. 6, the Schottky electrode 400 is formed on the n− type epitaxial layer 200 in the electrode area A. The Schottky electrode 400 extends to the terminal area B to make contact with the p area 300 under the first trench 210.

As shown in FIG. 1, on the second surface of the n+ type silicon carbide substrate 100, the ohmic electrode 500 is formed.

A method of manufacturing an SBD according to another exemplary embodiment of the present disclosure will now be described with reference to FIGS. 1 and 7 to 13.

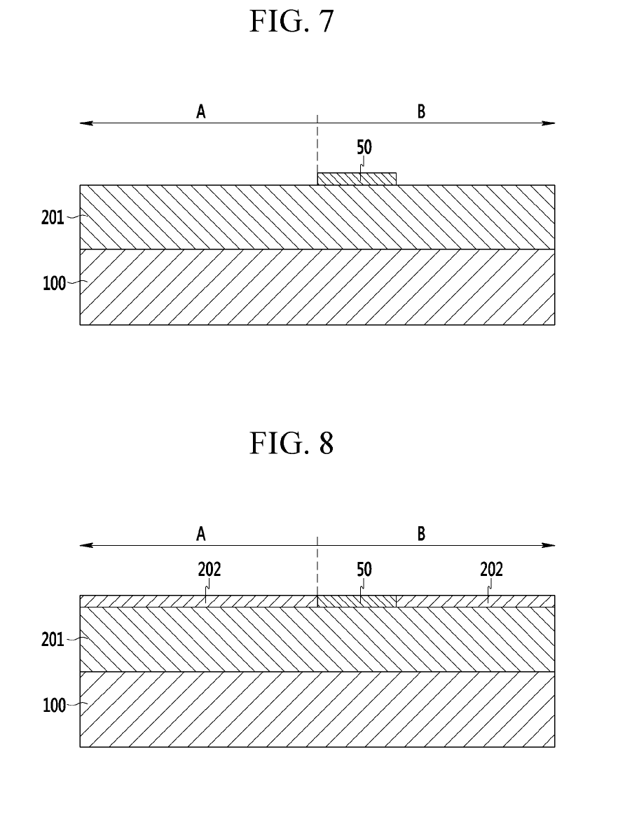

FIGS. 7 to 13 are cross-sectional views sequentially illustrating a method of manufacturing an SBD according to another exemplary embodiment of the present disclosure.

As shown in FIG. 7, an n+ type silicon carbide substrate 100 is prepared, and a first preliminary n− type epitaxial layer 201, including an electrode area A and a terminal area B positioned outside of the electrode area A, is formed with a first epitaxial growth on a first surface of the n+ type silicon carbide substrate 100. Thereafter, a first mask 50 is formed on a portion of the first preliminary n− type epitaxial layer 201 positioned in the terminal area B. The first mask 50 is formed adjacent to the electrode area A.

As shown in FIG. 8, a second preliminary n− type epitaxial layer 202 is formed on the first preliminary n− type epitaxial layer 201 with a second epitaxial growth. In this case, in a portion in which the first mask 50 is formed, the second epitaxial growth does not occur. The first mask 50 and the second preliminary n− type epitaxial layer 202 may have the same thickness.

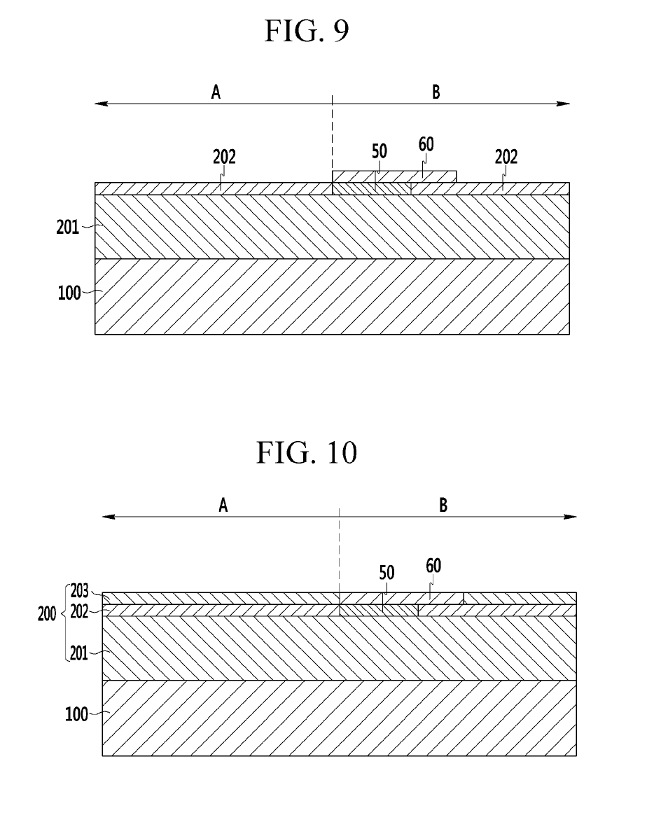

As shown in FIG. 9, a second mask 60 is formed on the first mask 50 and a portion of the second preliminary n− type epitaxial layer 202 positioned in the terminal area B. The second mask 60 may have a width larger than a width of the first mask 50.

As shown in FIG. 10, by forming a third preliminary n− type epitaxial layer 203 on the second preliminary n− type epitaxial layer 202 with a third epitaxial growth, the n− type epitaxial layer 200 is complete. That is, the n− type epitaxial layer 200 includes a first preliminary n− type epitaxial layer 201, a second preliminary n− type epitaxial layer 202, and a third preliminary n− type epitaxial layer 203. In this case, the third epitaxial growth does not occur in a portion in which the second mask 60 is formed. The second mask 60 and the third preliminary n− type epitaxial layer 203 may have the same thickness.

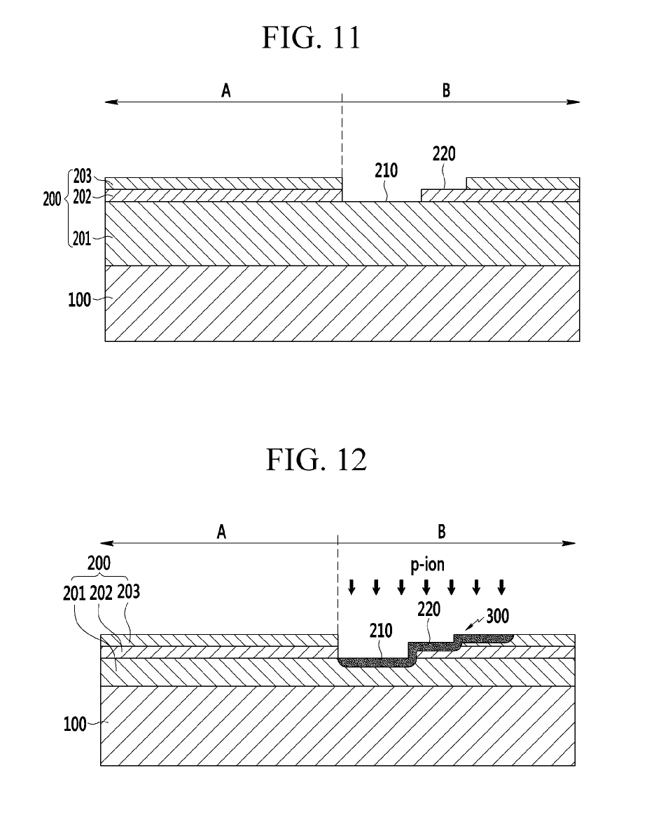

As shown in FIG. 11, by removing the first mask 50 and the second mask 60, a first trench 210 and a second trench 220 are formed. The first trench 210 and the second trench 220 are adjacently positioned to form a step, and a bottom of the first trench 210 is formed lower than a bottom of the second trench 220.

Further, the first trench 210 is positioned adjacent to the electrode area A, and the second trench 220 is positioned adjacent to an upper surface of the n− type epitaxial layer 200 in the terminal area B.

As shown in FIG. 12, by injecting p-ions into the first trench 210, the second trench 220, and a partial surface of the n− type epitaxial layer 200 in the terminal area B, a p area 300 is formed under the first trench 210, the second trench 220, and the partial surface of the n− type epitaxial layer 200 in the terminal area B.

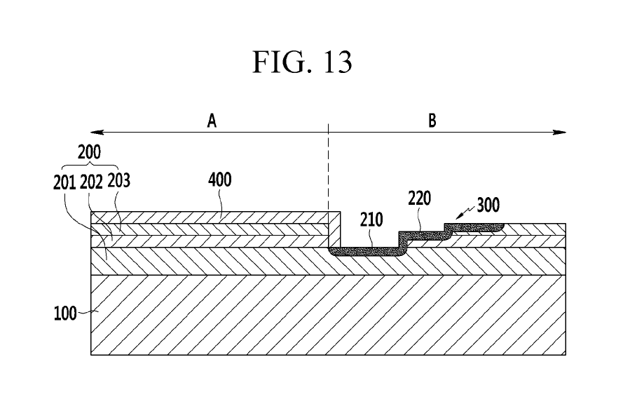

As shown in FIG. 13, a Schottky electrode 400 is formed on the n− type epitaxial layer 200 in the electrode area A. The Schottky electrode 400 extends to the terminal area B to make contact with the p area 300 under the first trench 210.

As shown in FIG. 1, on the second surface of the n+ type silicon carbide substrate 100, the ohmic electrode 500 is formed.

A method of manufacturing an SBD according to yet another exemplary embodiment of the present disclosure will be described with reference to FIGS. 1 and 14 to 24.

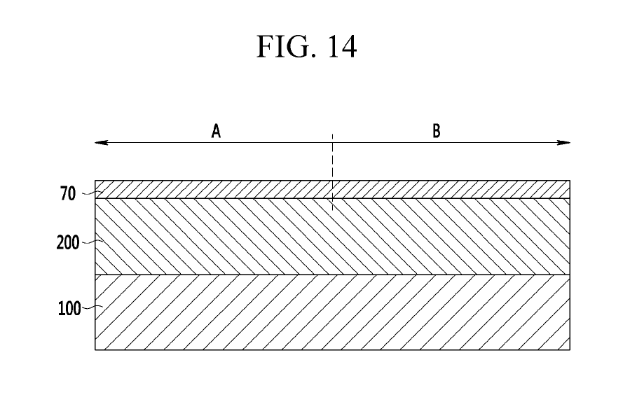

FIGS. 14 to 24 are cross-sectional views sequentially illustrating a method of manufacturing an SBD according to yet another exemplary embodiment of the present disclosure.

As shown in FIG. 14, the n+ type silicon carbide substrate 100 is prepared, and the n− type epitaxial layer 200 is formed with a first epitaxial growth on a first surface of the n+ type silicon carbide substrate 100. The n− type epitaxial layer 200 includes the electrode area A and the terminal area B positioned outside of the electrode area A.

Thereafter, a first buffer layer 70 is formed on the n− type epitaxial layer 200. The first buffer layer 70 may be made of amorphous carbon.

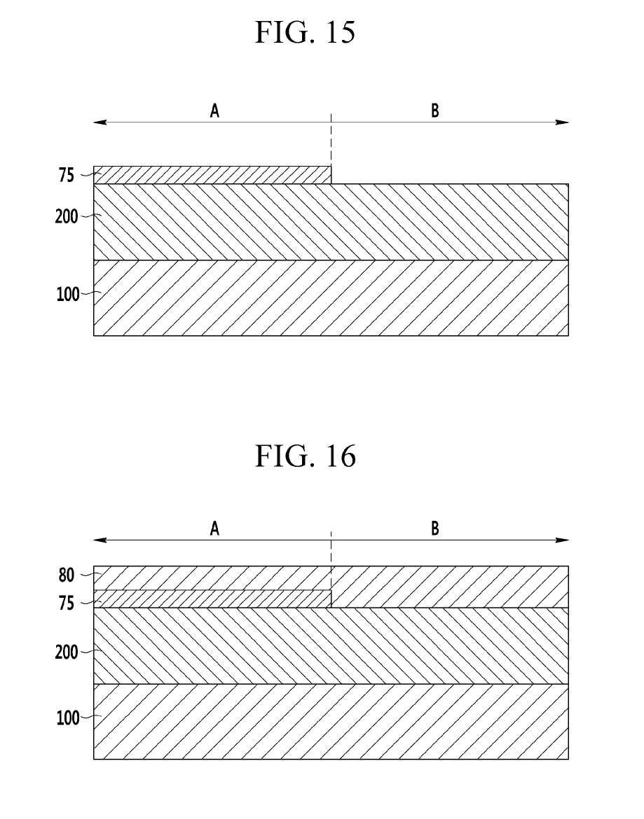

As shown in FIG. 15, by etching a portion of the first buffer layer 70 positioned in the terminal area B, a first buffer layer pattern 75 is formed. The first buffer layer pattern 75 is positioned on the n− type epitaxial layer 200 in the electrode area A and exposes the n− type epitaxial layer 200 in the terminal area B.

As shown in FIG. 16, a second buffer layer 80 is formed on the first buffer layer pattern 75 and the n− type epitaxial layer 200 in the terminal area B. The second buffer layer 80 is formed as an oxide layer.

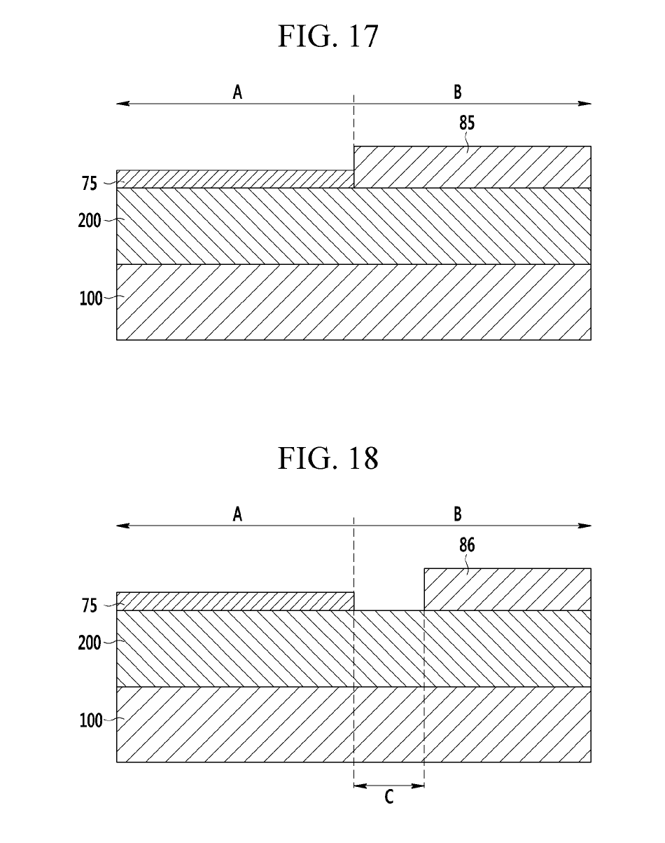

As shown in FIG. 17, by etching a portion of the second buffer layer 80 positioned on the first buffer layer pattern 75, a second buffer layer pattern 85 is formed. The second buffer layer pattern 85 is positioned on the n− type epitaxial layer 200 in the terminal area B and exposes the first buffer layer pattern 75. The second buffer layer pattern 85 may have a thickness larger than a thickness of the first buffer layer pattern 75.

As shown in FIG. 18, by etching a portion of the second buffer layer pattern 85, a third buffer layer pattern 86 is formed. In a contact portion of the first buffer layer pattern 75 and the second buffer layer pattern 85, first isotropic etching of the second buffer layer pattern 85 is performed in a horizontal direction. The third buffer layer pattern 86 exposes a first portion C of the n− type epitaxial layer 200. The first portion C of the n− type epitaxial layer 200 is positioned in the terminal area B and is positioned adjacent to the electrode area A.

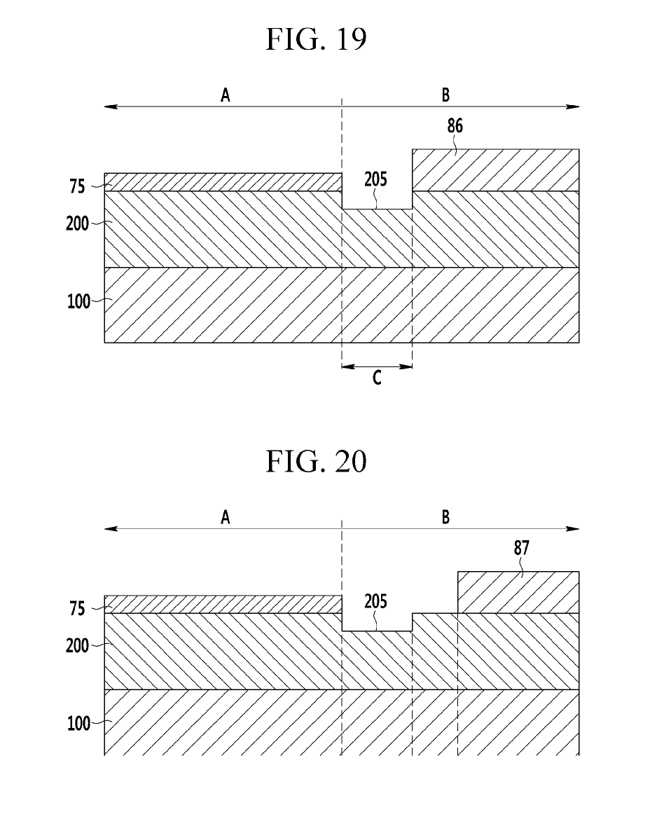

As shown in FIG. 19, by etching the first portion C of the n− type epitaxial layer 200, a preliminary trench 205 is formed. In this case, etching is performed in a vertical direction.

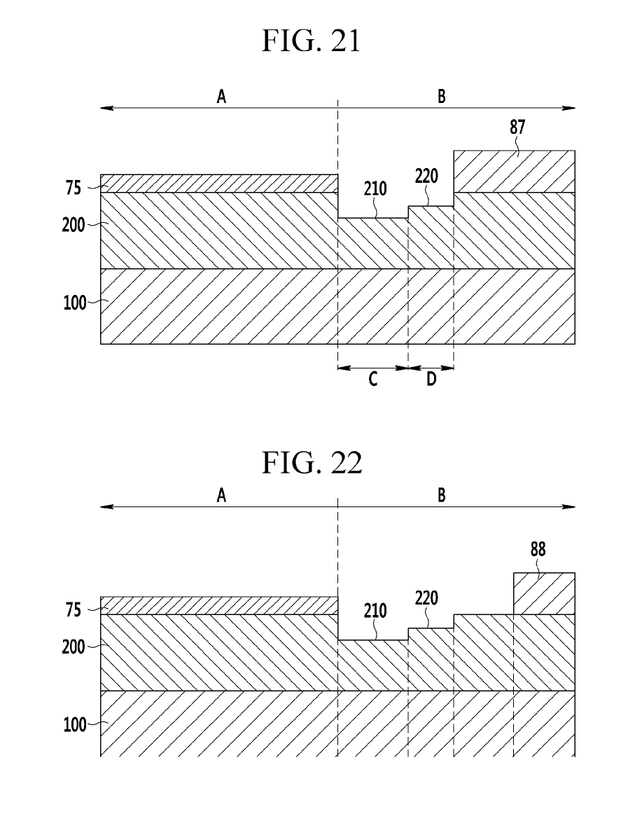

As shown in FIG. 20, by etching a portion of the third buffer layer pattern 86, a fourth buffer layer pattern 87 is formed. In a portion of the third buffer layer pattern 86 adjacent to the preliminary trench 205, second isotropic etching of the third buffer layer pattern 86 is performed in a horizontal direction. The fourth buffer layer pattern 87 exposes a second portion D (shown in FIG. 21) of the n− type epitaxial layer 200. The second portion D of the n− type epitaxial layer 200 is positioned in the terminal area B and is positioned adjacent to the preliminary trench 205.

As shown in FIG. 21, by etching the preliminary trench 205 and the second portion D of the n− type epitaxial layer 200, the first trench 210 and the second trench 220 are each formed.

The first trench 210 and the second trench 220 are adjacently positioned to form a step, and a bottom of the first trench 210 is formed lower than a bottom of the second trench 220.

Further, the first trench 210 is positioned adjacent to the electrode area A, and the second trench 220 is positioned adjacent to an upper surface of the n− type epitaxial layer 200 in the terminal area B.

In this way, the first trench 210 and the second trench 220 are formed using an existing buffer layer pattern without needing to use another etching mask. Further, by performing isotropic etching in a horizontal direction, the third buffer layer pattern 86 and the fourth buffer layer pattern 87 are formed and thus a width of the first trench 210 and a width of the second trench 220 can be adjusted more easily.

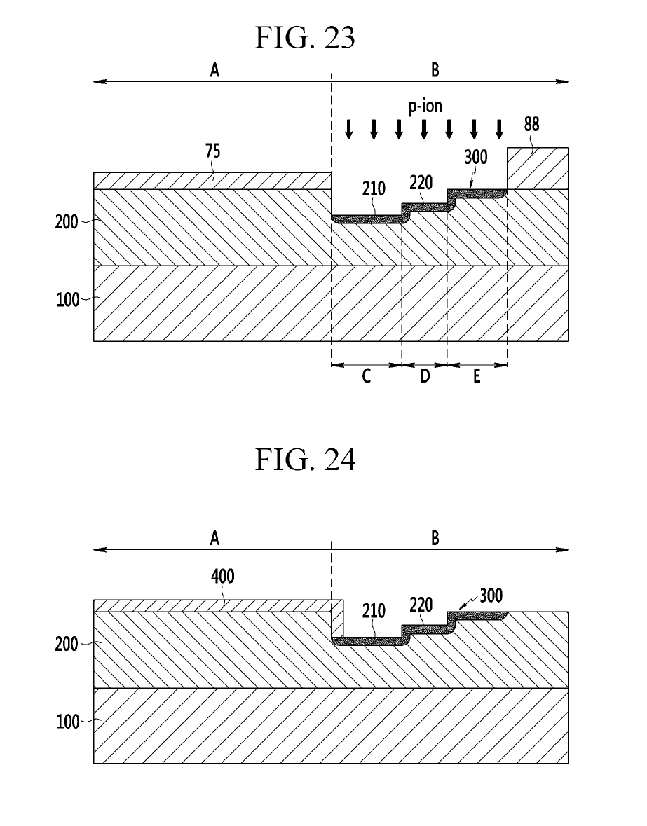

As shown in FIG. 22, by etching the fourth buffer layer pattern 87, a fifth buffer layer pattern 88 is formed. In this case, in a portion of the fourth buffer layer pattern 87 adjacent to the second trench 220, third isotropic etching of the fourth buffer layer pattern 87 is performed in a horizontal direction. The fifth buffer layer pattern 88 exposes a third portion E (shown in FIG. 23) of the n− type epitaxial layer 200. The third portion E of the n− type epitaxial layer 200 is positioned in the terminal area B and is positioned adjacent to the second trench 220.

As shown in FIG. 23, by injecting p-ions into the first trench 210, the second trench 220, and the third portion E of the n− type epitaxial layer 200, a p area 300 is formed under the first trench 210, the second trench 220, and the third portion E of the n− type epitaxial layer 200. In this case, p-ions are injected using the existing first buffer layer pattern 75 and fifth buffer layer pattern 88 as masks, without needing to use another mask.

As shown in FIG. 24, after removing the first buffer layer pattern 75 and the fifth buffer layer pattern 88, a Schottky electrode 400 is formed on the n− type epitaxial layer 200 positioned in the electrode area A. In this case, the first buffer layer pattern 75 is removed by performing, e.g., an ashing process, and the fifth buffer layer pattern 88 is removed by performing, e.g., wet etching.

The Schottky electrode 400 extends to the terminal area B to make contact with the p area 300 under the first trench 210.

As shown in FIG. 1, on the second surface of the n+ type silicon carbide substrate 100, the ohmic electrode 500 is formed.

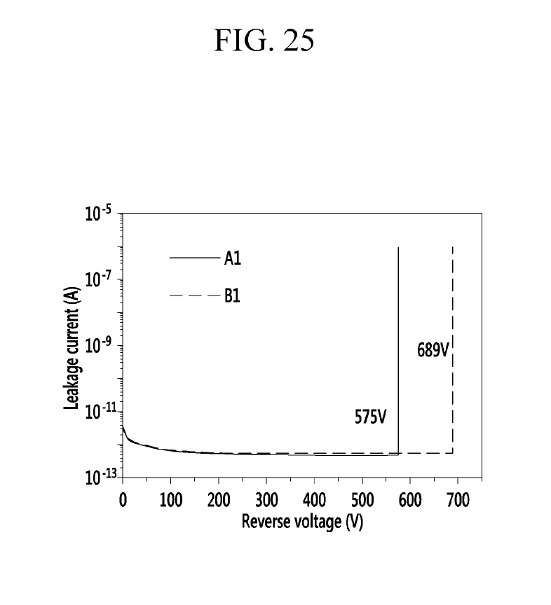

Hereinafter, characteristics of an SBD according to an exemplary embodiment of the present disclosure will be described with reference to FIG. 25.

FIG. 25 is a graph comparing breakdown voltages of an SBD according to an exemplary embodiment of the present disclosure and a conventional SBD.

In FIG. 25, A1 represents a breakdown voltage of a conventional SBD, and B1 represents a breakdown voltage of an SBD according to the present disclosure.

As shown in FIG. 25, a breakdown voltage of the SBD according to the present disclosure was 689V, and a breakdown voltage of the conventional SBD was 575V. Accordingly, it can be seen that a breakdown voltage of the SBD according to the present disclosure is improved by about 20%, compared with a breakdown voltage of the conventional SBD.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

<Description of symbols>

| | |
|---|---|
| 50: first mask | 60: second mask |
| 70: first buffer layer | 75: first buffer layer pattern |
| 80: second buffer layer | 85: second buffer layer pattern |
| 86: third buffer layer pattern | 87: fourth buffer layer pattern |
| 88: fifth buffer layer pattern | |
| 100: n+ type silicon carbide substrate | |
| 200: n− type epitaxial layer | 201: first preliminary epitaxial |
| | layer |
| 202: second preliminary epitaxial layer | |
| 203: third preliminary epitaxial layer | |
| 205, 225: preliminary trench | 210: first trench |
| 220: second trench | 300: p area |
| 400: Schottky electrode | 500: ohmic electrode |

What is claimed is:

1. A Schottky barrier diode, comprising:
an n+ type silicon carbide substrate;
an n− type epitaxial layer disposed on a first surface of the n+ type silicon carbide substrate and including an electrode area and a terminal area positioned outside of the electrode area;
a first trench and a second trench disposed on the n− type epitaxial layer in the terminal area;
a p area disposed under the first trench and the second trench;
a Schottky electrode disposed on the n− type epitaxial layer in the electrode area; and
an ohmic electrode disposed on a second surface of the n+ type silicon carbide substrate,
wherein the first trench and the second trench are adjacently positioned to form a step.

2. The Schottky barrier diode of claim 1, wherein a bottom of the first trench is disposed lower than a bottom of the second trench.

3. The Schottky barrier diode of claim 2, wherein the first trench is positioned adjacent to the electrode area.

4. The Schottky barrier diode of claim 3, wherein the p area extends to an upper surface of the n− type epitaxial layer in the terminal area adjacent to the second trench.

5. The Schottky barrier diode of claim 4, wherein the Schottky electrode extends to the terminal area to make contact with the p area.

6. A method of manufacturing a Schottky barrier diode, the method comprising:
forming an n− type epitaxial layer, including an electrode area and a terminal area positioned outside of the electrode area, with a first epitaxial growth on a first surface of an n+ type silicon carbide substrate;
forming a preliminary trench by etching a portion of the n− type epitaxial layer in the terminal area;
forming a first trench and a second trench by etching a portion of the preliminary trench;
forming a p area under the first trench, the second trench, and an upper surface of the n− type epitaxial layer in the terminal area adjacent to the second trench, by injecting p-ions into the first trench, the second trench, and the upper surface of the n− type epitaxial layer in the terminal area adjacent to the second trench;
forming a Schottky electrode on the n− type epitaxial layer in the electrode area; and
forming an ohmic electrode on a second surface of the n+ type silicon carbide substrate,
wherein the first trench and the second trench are adjacently positioned to form a step.

7. The method of claim 6, wherein a bottom of the first trench is positioned lower than a bottom of the second trench.

8. The method of claim 7, wherein the first trench is formed adjacent to the electrode area.

9. The method of claim 8, wherein the Schottky electrode extends to the terminal area to make contact with the p area.

10. A method of manufacturing a Schottky barrier diode, the method comprising:
forming a first preliminary n− type epitaxial layer, including an electrode area and a terminal area positioned outside of the electrode area, with a second epitaxial growth on a first surface of an n+ type silicon carbide substrate;
forming a first mask on a portion of the first preliminary n− type epitaxial layer in the terminal area;
forming a second preliminary n− type epitaxial layer with a third epitaxial growth on the first preliminary n− type epitaxial layer;
forming a second mask on the first mask and on a portion of the second preliminary n− type epitaxial layer in the terminal area;
forming a third preliminary n− type epitaxial layer with a fourth epitaxial growth on the second preliminary n− type epitaxial layer, thereby forming an n− type epitaxial layer;
forming a first trench and a second trench by removing the first mask and the second mask;
forming a p area under the first trench, the second trench, and an upper surface of the n− type epitaxial layer in the terminal area adjacent to the second trench, by injecting p-ions into the first trench, the second trench, and the upper surface of the n− type epitaxial layer in the terminal area adjacent to the second trench;
forming a Schottky electrode on the n− type epitaxial layer in the electrode area; and
forming an ohmic electrode on a second surface of the n+ type silicon carbide substrate,
wherein the first trench and the second trench are adjacently positioned to form a step.

11. The method of claim 10, wherein a bottom of the first trench is positioned lower than a bottom of the second trench.

12. The method of claim 11, wherein the first trench is formed adjacent to the electrode area.

13. The method of claim 12, wherein the Schottky electrode extends to the terminal area to make contact with the p area.

14. The method of claim 10, wherein the second mask has a width larger than a width of the first mask.

15. The method of claim 14, wherein the first mask and the second preliminary n− type epitaxial layer have the same thickness.

16. The method of claim 15, wherein the second mask and the third preliminary n− type epitaxial layer have the same thickness.

17. A method of manufacturing a Schottky barrier diode, the method comprising:
forming an n− type epitaxial layer, including an electrode area and a terminal area positioned outside of the electrode area, with an epitaxial growth on a first surface of an n+ type silicon carbide substrate, and forming a first buffer layer on the n− type epitaxial layer;
forming a first buffer layer pattern that exposes the n− type epitaxial layer in the terminal area by etching a portion of the first buffer layer positioned in the terminal area;
forming a second buffer layer on the first buffer layer pattern and on the n− type epitaxial layer in the terminal area;
forming a second buffer layer pattern that exposes the first buffer layer pattern by etching a portion of the second buffer layer positioned on the first buffer layer pattern;
forming a third buffer layer pattern that exposes a first portion of the n− type epitaxial layer by performing a first isotropic etching of the second buffer layer pattern in a horizontal direction;
forming a preliminary trench by etching the first portion of the n− type epitaxial layer;
forming a fourth buffer layer pattern that exposes a second portion of the n− type epitaxial layer by performing a second isotropic etching of the third buffer layer pattern in a horizontal direction;
forming a first trench and a second trench by etching the preliminary trench and the second portion of the n− type epitaxial layer, respectively;
forming a fifth buffer layer pattern that exposes a third portion of the n− type epitaxial layer by performing a third isotropic etching of the fourth buffer layer pattern in a horizontal direction;
forming a p area under the first trench, the second trench, and the third portion of the n− type epitaxial layer by injecting p-ions into the first trench, the second trench, and the third portion of the n− type epitaxial layer;
forming a Schottky electrode on the n− type epitaxial layer in the electrode area; and
forming an ohmic electrode on a second surface of the n+ type silicon carbide substrate,
wherein the first trench and the second trench are adjacently positioned to form a step.

18. The method of claim 17, wherein a bottom of the first trench is positioned lower than a bottom of the second trench.

19. The method of claim 18, wherein the first trench is formed adjacent to the electrode area.

20. The method of claim 19, wherein the Schottky electrode extends to the terminal area to make contact with the p area.

21. The method of claim 17, wherein the first buffer layer pattern is positioned in the electrode area, and the second buffer layer pattern is positioned in the terminal area, and
the first buffer layer pattern and the second buffer layer pattern contact each other.

22. The method of claim 21, wherein the first isotropic etching is performed in a contact portion of the first buffer layer pattern and the second buffer layer pattern.

23. The method of claim 22, wherein the preliminary trench and the third buffer layer pattern are adjacently positioned, and
the second isotropic etching is performed in a portion of the third buffer layer pattern adjacent to the preliminary trench.

24. The method of claim 23, wherein the second trench and the fourth buffer layer pattern are adjacently positioned, and
the third isotropic etching is performed in a portion of the fourth buffer layer pattern adjacent to the second trench.

25. The method of claim 17, wherein the first buffer layer is made of amorphous carbon, and
the second buffer layer is formed with an oxide layer.
